(19) United States
(12) Patent Application Publication
(10) Pub. No.: US 2010/0157704 A1
(43) Pub. Date: Jun. 24, 2010

(54) Semiconductor memory device that can relief defective address

(75) Inventor: Hiroaki Iwaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/654,285

(22) Filed: Dec. 16, 2009

(30) Foreign Application Priority Data
Dec. 19, 2008 (JP) 2008-323434

(51) Int. Cl. G11C 29/00; G11C 8/00; G11C 17/16

(52) U.S. Cl. 365/200; 365/230.08; 365/225.7; 365/194; 365/233.1

(57) ABSTRACT

Plural nonvolatile address storing circuits hold address data. A serial transfer circuit sequentially transfers the address data stored in each of the nonvolatile address storing circuits. A serial reception circuit sequentially receives the address data transferred by the serial transfer circuit. An address latch circuit holds the address data received by the serial reception circuit. An address comparison circuit compares each of the address data stored in the address latch circuit with an input address, and determines whether each address data coincides with the input address.

### BACKGROUND OF THE INVENTION

1. Field of the Invention

The present invention relates to a semiconductor memory device, and more particularly relates to a semiconductor memory device that can relieve bit defects generated sporadically.

2. Description of Related Art

Memory capacities of semiconductor memory devices such as DRAM (Dynamic Random Access Memory) have been increased year by year according to improvements of micro-fabrication technology. However, as the size of semiconductor memory device is downscaled, the number of defective memory cells per chip has been increased. Such defective memory cells are replaced by redundant memory cells to relieve defective addresses.

In general, defective addresses are registered in plural program fuses included in a fuse circuit. When an access to any of the defective addresses is requested, an alternate access to a redundant memory cell is performed, instead of the defective memory cell itself, in the control of the fuse circuit. This defective address is detected by a selection test performed in a wafer state. A laser beam is irradiated to the program fuse corresponding to the detected defective address and the irradiated program fuse is disconnected.

However, even after address replacement, a defective bit is sporadically generated due to thermal stress and the like at packaging. If the defective bit is found after the packaging, an address cannot be replaced anymore by irradiating a laser beam. Accordingly, a chip which has such kind of defective bit has to be handled as a defective product.

To solve such problems, in addition to a primary redundancy operation by irradiating a laser beam, a secondarily redundancy operation for a small number of defective bits found after the packaging has been proposed. In this case, to constitute a circuit that stores a defective address to be secondarily relieved, a laser fuse circuit that requires laser beam irradiation is not used, but an electrically writable nonvolatile memory circuit is used. A so-called “antifuse circuit” using dielectric breakdown of an oxide film can be used for the memory circuit.

The number of defective bits found after packaging is considerably smaller than that of defective bits found in a selection test. Therefore, preferably, a secondary redundancy operation using an antifuse element is performed by replacing an address by a memory cell, instead of replacing addresses by a word line or a bit line unit.

To replace an address by a memory cell, both a row address and a column address need to be referred, and coincidence of both addresses needs to be detected in detecting a defective address. This means that the number of bits of an address to specify a defective memory cell is very large. That is, to replace addresses belonging to a same word line, it is sufficient to detect coincidence of row addresses, and it is not necessary to refer to a column address. Similarly, to replace addresses belonging to a same bit line, it is sufficient to detect coincidence of column addresses, and it is not necessary to refer to a row address. On the other hand, to replace an address by a memory cell, both a row address and a column address need to be referred, and the number of bits necessary to compare addresses is inevitably large. As a result, the number of transfer lines necessary to transmit address data becomes large.

As a method of reducing the number of transfer lines necessary to transmit address data, a method disclosed in Japanese Patent Application Laid-open No. 2000-182394 has been known. This conventional method achieves transmission of address data by using one signal line, by transmitting each one bit of address data stored in a laser fuse circuit.

However, Japanese Patent Application Laid-open No. 2000-182394 discloses a method for a primary redundancy operation of replacing addresses by a word line or a bit line. As described above, in the primary redundancy operation, only one of a row address and a column address is used. Therefore, the number of bits of address data to specify a defective memory cell is small. Accordingly, it does not take a long time to transmit address data, even if the address data is transmitted by using one signal line.

On the other hand, in the secondary redundancy operation of replacing an address by a memory cell, both a row address and a column address are used, and the number of bits of address data is large. Accordingly, if address data is transmitted via one signal line, it takes a longtime for this transmission, and there can be a problem that transmission of the address data is not completed within a predetermined initialization period.

Therefore, there has been desired a semiconductor memory device capable of reducing the time to transmit address data while reducing the number of transfer lines to transmit address data.

### SUMMARY

The present invention seeks to solve one or more of the above problems, or to improve upon those problems at least in part.

In one embodiment, there is provided a semiconductor memory device comprising: a memory cell array that may include a plurality of first defective memory cells; a plurality of nonvolatile address storing circuits that store respectively a plurality of first sets of defective address data, each of the first sets of defective address data indicating a corresponding one of the first defective memory cells and including a plurality of first address data; a serial transfer circuit that transfers in parallel the address data of each of the first sets of defective address data and in serial the first sets of defective address data stored in each of the nonvolatile address storing circuits; a serial reception circuit that receives in parallel the address data of each of the first sets of defective address data and in serial the sets of defective address data from the serial transfer circuit; and a plurality of address latch circuits that receive and store respectively the first sets of defective address data supplied from the serial reception circuit.

In another embodiment, there is provided a semiconductor memory device comprising: a memory cell array that may include a plurality of first defective memory cells; a plurality of nonvolatile address storing circuits that store respectively a plurality of first sets of defective address data, each of the first sets of defective address data indicating a corresponding one of the first defective memory cells and including a plurality of first address data; a plurality of transfer lines that transfers in parallel each of the first sets of defective address data, the number of the transfer lines being equal to the number of bits of the first address data included in each of the first defective address data; and an address comparison circuit that compares the each of the first sets of defective address data transferred via the transfer lines with an input address, and determines whether one of the first sets of defective address data coincides with the input address.

According to the present invention, address data to specify one defective memory cell is transmitted as one unit. Therefore, the time to transmit address data can be shortened while reducing the number of transfer lines to transmit the address data.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic diagram for explaining a method of a two-stage redundancy operation of a semiconductor memory device according to an embodiment of the present invention;

FIG. 2A is a schematic diagram for explaining a method of replacement by a word line in a primary redundancy operation;

FIG. 2B is a schematic diagram for explaining a method of replacement by a bit line in a primary redundancy operation;

FIG. 2C is a schematic diagram for explaining a method of replacement by a memory cell in a secondary redundancy operation;

FIG. 3 is a schematic block diagram of the secondary relief circuit (a secondary redundancy control circuit) and the antifuse circuit;

FIG. 4 is a schematic block diagram of the circuit shown in FIG. 3 in more detail;

FIG. 5 is a block diagram showing a configuration of a memory circuit for one bit included in an antifuse element group;

FIG. 6 is a timing chart showing a redundancy control operation of the semiconductor memory device;

FIG. 7 is a timing chart showing a load operation of a secondary relief address data (address data used for the secondary redundancy operation); and

FIG. 8 is a timing chart showing an example of load operation of a secondary relief address data (address data used for the secondary redundancy operation) using one transfer wiring for comparison.

### DETAILED DESCRIPTION OF THE EMBODIMENTS

Preferred embodiments of the present invention will be explained below in detail with reference to the accompanying drawings.

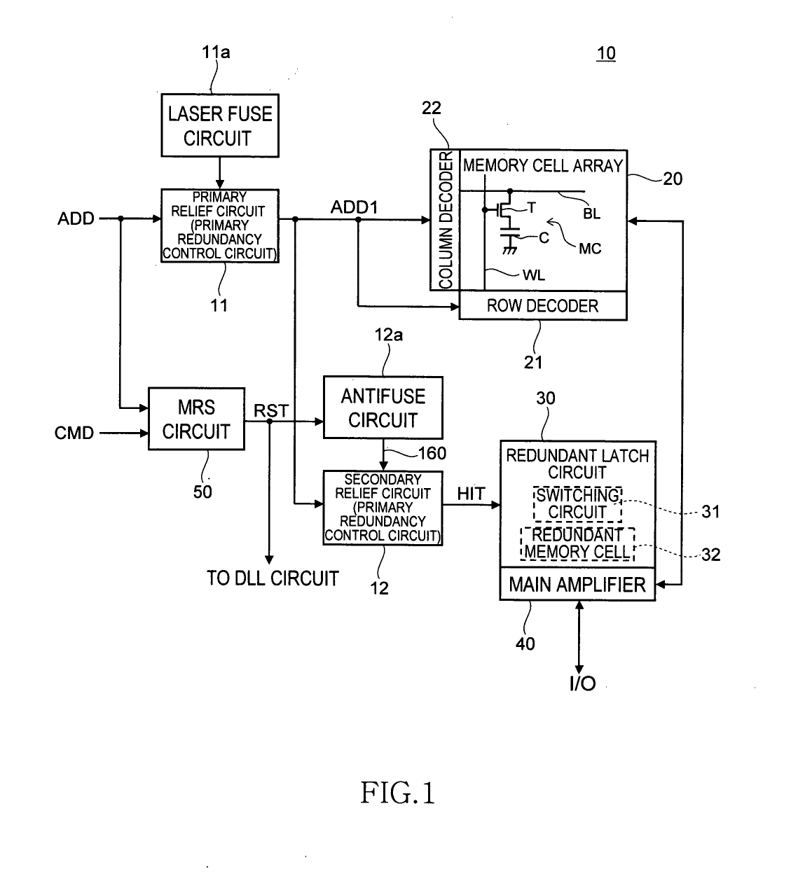

FIG. 1 is a schematic diagram for explaining a method of a two-stage redundancy operation of a semiconductor memory device 10 according to an embodiment of the present invention.

As shown in FIG. 1, the semiconductor memory device 10 includes a primary relief circuit (a primary redundancy control circuit) 11 that refers to an input address ADD input from outside and relieves a defective address included in the address ADD, and a secondary relief circuit (a secondary redundancy control circuit) 12 that relieves a defective address still included in an address ADD1 relieved by the primary relief circuit (the primary redundancy control circuit) 11.

The primary relief circuit (the primary redundancy control circuit) 11 relieves a defective address detected by an operation test in a wafer state. This defective address is thereafter permanently held in a laser fuse circuit 11a. The secondary relief circuit (the secondary redundancy control circuit) 12 relieves a defective address detected after packaging, and the defective address is permanently held in an antifuse circuit 12a. The defective address is programmed into the laser fuse circuit 11a by irradiating a laser beam. On the other hand, the defective address is written into the antifuse circuit 12a by applying a high voltage to an insulation film included in an antifuse element, and by dielectrically breaking down the insulation film. Both fuse circuits 11a, 12a can hold addresses in a nonvolatile and irreversible manner.

A row address of the address ADD1 after relieved by the primary relief circuit (the primary redundancy control circuit) 11 is supplied to a row decoder 21, and a column address of the address ADD1 is supplied to a column decoder 22. The row decoder 21 selects a word line WL of a memory cell array 20. The column decoder 22 selects a bit line BL of the memory cell array 20. A memory cell MC is arranged at an intersection of the word line WL and the bit line BL. The memory cell MC is a series circuit of a cell transistor T and a cell capacitor C. A gate of the cell transistor T is connected to a corresponding word line WL, and a source and a drain of the cell transistor T are connected to a corresponding bit lime BL.

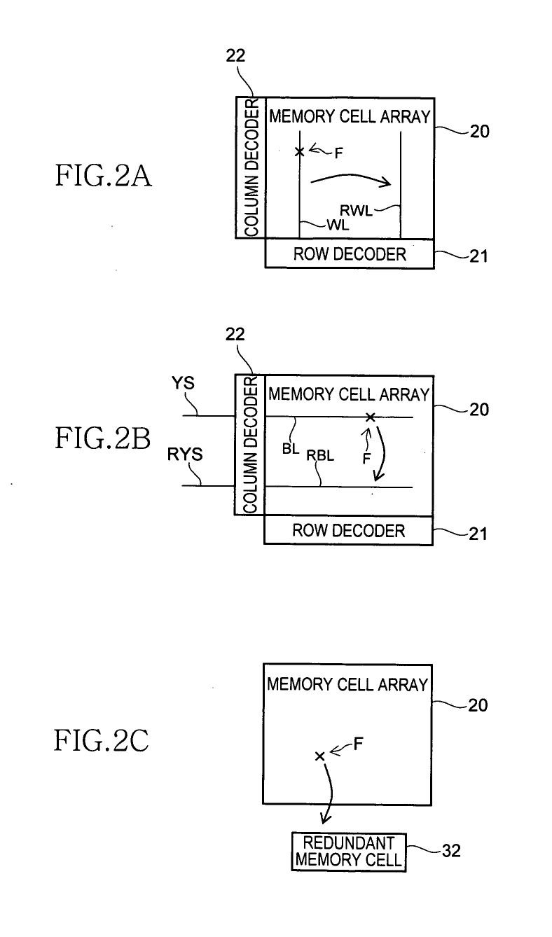

As shown in FIG. 2A, the memory cell array 20 includes a redundant word line RWL in addition to the word line WL. When a defective word line (or a word line connected to a defective bit F) is found by an operation test performed in a wafer state, this word line WL is replaced by the redundant word line RWL. In this case, a row address (a defective row address) indicating a defective word line is written into the laser fuse circuit 11a. When the row address in the input address ADD coincides with the defective row address, the primary relief circuit (the primary redundancy control circuit) 11 performs address conversion and an alternate access to the redundant word line RWL is performed instead of an access to the defective word line.

As shown in FIG. 2B, the memory cell array 20 includes a redundant column selection line RYS in addition to a column selection line YS. When a defective bit line (or a bit line connected to the defective bit F) is found by an operation test performed in a wafer state, the column selection line YS corresponding to this bit line is replaced by the redundant-column selection line RYS. In this case, a column address (a defective column address) indicating a defective bit line is written into the laser fuse circuit 11a. When the column address in the input address ADD coincides with the defective column address, the primary relief circuit (the primary redundancy control circuit) 11 performs address conversion and selects the redundant-column selection line RYS corresponding to a redundant bit line RBL instead of the column selection line YS corresponding to the defective bit line.

As explained above, in the address relief operation (the primary redundancy operation) by the primary relief circuit (the primary redundancy control circuit) 11, a redundant word line and a redundant bit line within the memory cell array 20 are used.

Further, the address ADD1 relieved by the primary relief circuit (the primary redundancy control circuit) 11 is also supplied to the secondary relief circuit (the secondary redundancy control circuit) 12. The secondary relief circuit (the secondary redundancy control circuit) 12 relieves a defective bit sporadically generated due to thermal stress and the like at packaging, after relief operation (the primary redundancy operation) by the primary relief circuit (the primary redundancy control circuit) 11. As shown in FIG. 2C, for the secondary relief circuit (the secondary redundancy control circuit) 12 to replace the defective bit, a redundant memory cell 32 provided at the outside of the memory cell array 20 is used.

The secondary relief circuit (the secondary redundancy control circuit) 12 relieves a defective bit by a memory cell. Therefore, to detect a defective address, both a row address and a column address are necessary. Accordingly, address data including both a row address and a column address is written into the antifuse circuit 12a, to specify a defective bit. When the address ADD1 after a primary redundancy operation coincides with the address written in the antifuse circuit 12a, a hit determination signal HIT is activated. When the hit determination signal HIT is activated, a switching circuit 31 in a redundant latch circuit 30 switches an access path to a defective memory cell to an access path to the redundant memory cell 32. Consequently, an alternate access is made to the redundant memory cell 32, not to the defective bit, included in the memory cell array 20. For example, the redundant memory cell 32 is made of an SRAM cell, and is arranged in a circuit region in which a main amplifier 40 is provided.

As shown in FIG. 1, the semiconductor memory device 10 according to the present embodiment further includes a mode register set (MRS) circuit 50. The MRS circuit 50 generates a signal for setting various kinds of operation modes of the semiconductor memory device 10 according to a predetermined code input as an address signal from outside, when a mode register setting command (MRS command) is input from the outside. FIG. 1 shows a reset signal (RST) of a DLL circuit, as one of signals generated by the MRS circuit 50. As described later, in the present embodiment, the reset signal (RST) of the DLL circuit is also used as a control signal of the antifuse circuit 12a. Therefore, the MRS circuit 50 is also configured to supply the reset signal (RST) of the DLL circuit to the antifuse circuit 12a.

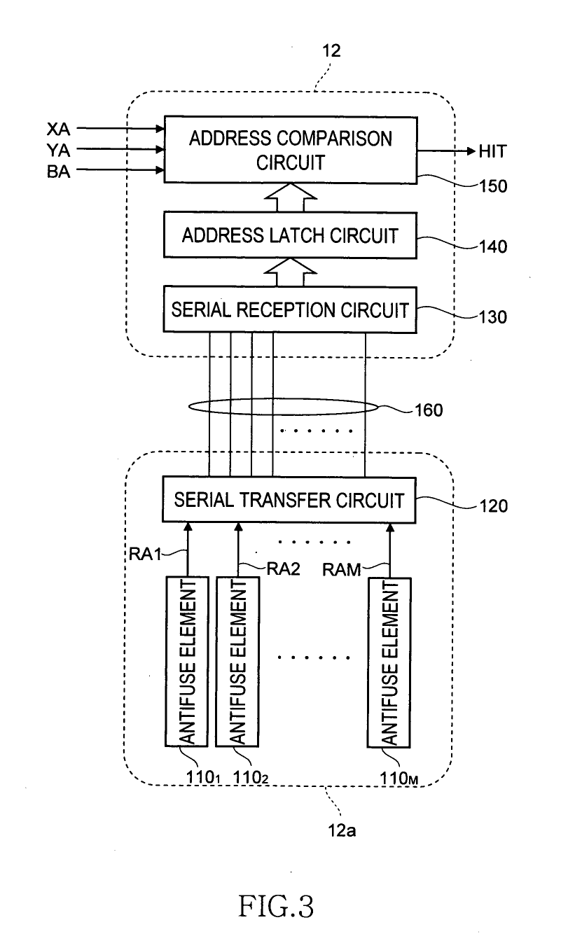

FIG. 3 is a schematic block diagram of the secondary relief circuit (the secondary redundancy control circuit) 12 and the antifuse circuit 12a.

As shown in FIG. 3, the antifuse circuit 12a includes M antifuse element groups 110₁ to 110_{M}, and a serial transfer circuit 120. The antifuse element groups 110₁ to 110_{M} hold address data RA1 to RAM specifying a defective memory cell, respectively, and constitute a nonvolatile address storing circuit. Therefore, the antifuse element groups 110₁ to 110_{M} can store M defective addresses.

The address data RA1 to RAM output from the M antifuse element groups 110₁ to 110_{M} are transferred to the secondary relief circuit (the secondary redundancy control circuit) 12 by the serial transfer circuit 120. Each of these address data RA1 to RAM is configured by a row address, a column address, a bank address, and an enable bit indicating whether these addresses are effective. The total of the row address, the column address, the bank address, and the enable bit is N bits.

On the other hand, the secondary relief circuit (the secondary redundancy control circuit) 12 includes: a serial reception circuit 130 that receives the address data RA1 to RAM transferred by the serial transfer circuit 120; an address latch circuit 140 that holds the address data RA1 to RAM received by the serial reception circuit 130; and an address comparison circuit 150 that compares each of the address data RA1 to RAM temporarily stored in the address latch circuit 140 with the input address ADD1 relieved by the primary relief circuit (the primary redundancy control circuit) 11, and determines whether each address data coincides with the input address. The input address ADD1 to the address comparison circuit 150 includes a row address XA, a column address YA, and a bank address BA. When the address ADD1 coincides with any one of the address data RA1 to RAM as a result of the comparison, the address comparison circuit 150 activates the hit determination signal HIT for indicating that this address is a defective address. The hit determination signal HIT is supplied to the redundant latch circuit 30 shown in FIG. 1.

As shown in FIG. 3, the serial transfer circuit 120 and the serial reception circuit 130 are connected to each other via N transfer lines 160. That is, the number (=N) of the transfer lines 160 is equal to the number (=N) of bits (address bits) constituting each of the address data RA1 to RAM. As described later, the serial transfer circuit 120 sequentially transmits the address data RA1 to RAM of the N bits (address bits) to the transfer wiring lines 160. The serial reception circuit 130 sequentially receives the address data RA1 to RAM of the N bits (address bits) supplied via the transfer lines 160. That is, the address data RA1 to RAM are serially transferred by the address bits.

The secondary relief circuit (the secondary redundancy control circuit) 12 and the antifuse circuit 12a are not arranged adjacently to each other, but are arranged in separate regions on a chip. This is because a size of an antifuse element in the antifuse circuit 12a is relatively large, all circuits shown in FIG. 3 cannot be easily arranged collectively in one region on the chip.

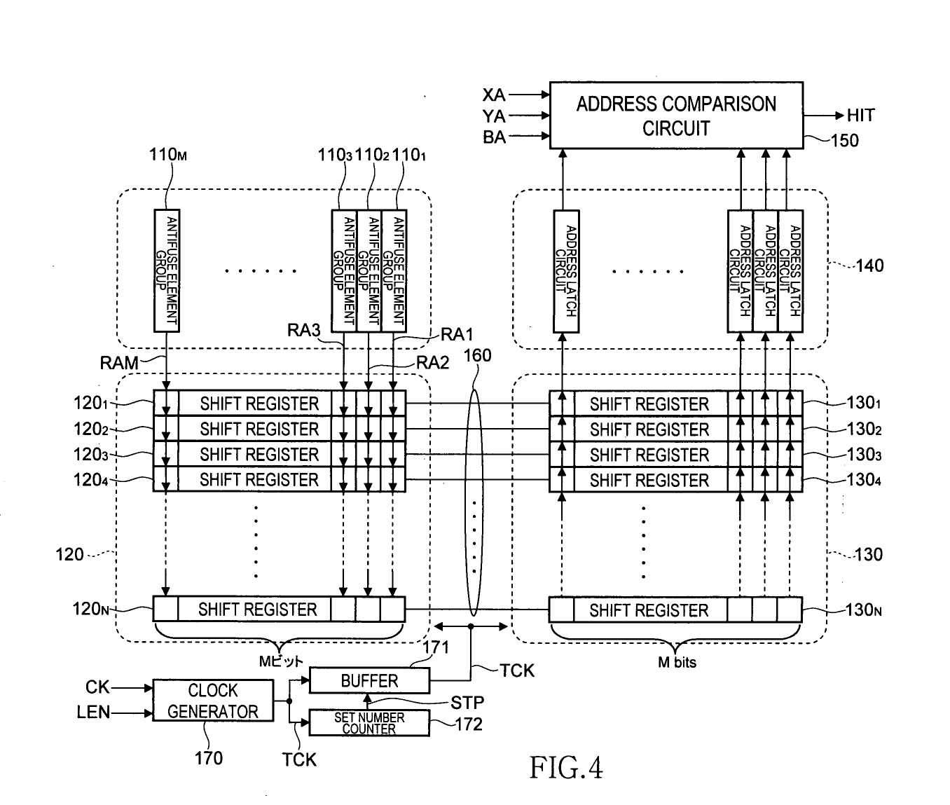

FIG. 4 shows the circuit shown in FIG. 3 in more detail.

As shown in FIG. 4, the serial transfer circuit 120 includes N shift registers 120₁ to 120_{N}. Each of the shift registers 120₁ to 120_{N} includes M bits. That is, a number of bits stored in each of the shift registers 120₁ to 120_{N} is equal to the number of the antifuse element groups 110₁ to 110_{M}. Address data are transferred in parallel from the antifuse element groups 110₁ to 110_{M} to the shift registers 120₁ to 120_{N}, and the address data are loaded on corresponding bit of the shift registers 120₁ to 120_{N}. Address data stored in the first antifuse element group 110₁ are loaded on a first bit of the shift registers 120₁ to 120_{N}, and address data stored in the second antifuse element group 110₂ are loaded on a second bit of the shift registers 120₁ to 120_{N}.

The serial reception circuit 130 also includes N shift registers 130₁ to 130_{N}. Each of the shift registers 130₁ to 130_{N} includes M bits. The shift registers 120₁ to 120_{N} that constitute the serial transfer circuit 120 and the shift registers 130₁ to 130_{N} that constitute the serial reception circuit 130 are connected to each other via N transfer lines 160₁ to 160_{N}, respectively. That is, corresponding two shift registers are connected to each other via one transfer wiring 160ᵢ (i=1 to N).

A clock generator 170 controls a transfer operation of address data from the serial transfer circuit 120 to the serial reception circuit 130. The clock generator 170 generates a transfer clock TCK, based on an external clock CK supplied from outside and a load enable signal LEN described later. The transfer clock TCK is supplied to the serial transfer circuit 120 and the serial reception circuit 130 via a buffer 171. The serial transfer circuit 120 serially transfers the address data RA1 to RAM synchronously with the transfer clock TCK. Similarly, the serial reception circuit 130 serially receives the address data RA1 to RAM synchronously with the transfer clock TCK.

The transfer clock TCK is also supplied to a set number counter 172. The set number counter 172 counts the transfer clock TCK. When the count reaches a predetermined value, the set number counter 172 outputs a stop signal STP to the buffer 171. Upon receiving the stop signal STP, the buffer 171 stops supplying the transfer clock TCK. In the present embodiment, a number set in advance to the set number counter 172 is M.

Plural address data transferred to the serial reception circuit 130 is loaded in parallel on the address latch circuit 140. The address latch circuit 140 includes M address latch circuits 140₁ to 140_{M}, and each address latch circuit latches address data corresponding to one defective bit. The address latch circuits 140₁ to 140_{M} hold the address data in a volatile manner, and are different in this respect from the antifuse element groups 110₁ to 110_{M} that hold address data in a nonvolatile manner. Because of this difference, the address latch circuits 140₁ to 140_{M} have substantially smaller areas on the chip than the antifuse element groups 1101 to 110M, although data sizes of stored address data are the same.

The address comparison circuit 150 compares the address data RA1 to RAM latched in the address latch circuits 140₁ to 140_{M} with the input address ADD1. As described above, the input address ADD1 includes the row address XA, the column address YA, and the bank address BA. When all of these addresses coincide with any one of the address data RA1 to RAM, the hit determination signal HIT is activated.

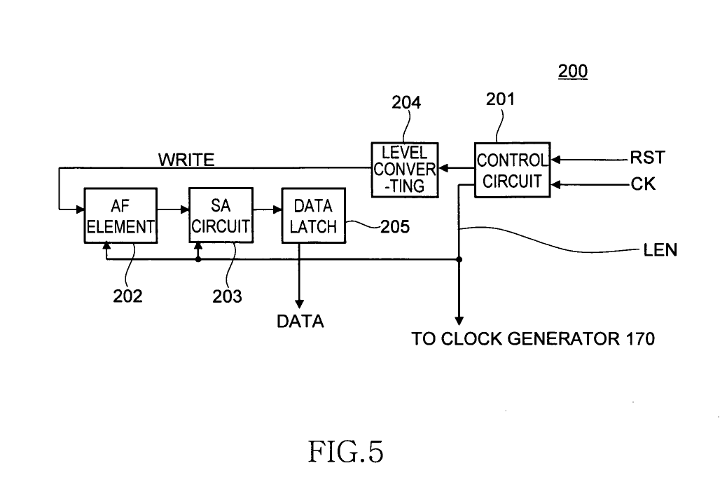

FIG. 5 is a block diagram showing a configuration of a memory circuit 200 for one bit included in an antifuse element group 110.

As shown in FIG. 5, the memory circuit 200 for one bit includes a control circuit 201 that receives the control signal RST supplied from the MRS circuit 50 shown in FIG. 1 and the external clock CK, and generates a load enable signal LEN. The control signal RST is a signal for resetting the DLL circuit, and is activated when a semiconductor memory device is initialized. The load enable signal LEN is supplied to the clock generator 170 shown in FIG. 4, and is also supplied to an antifuse element 202 and a sense amplifier circuit 203.

The antifuse element 202 is capable of storing one-bit data by dielectric breakdown in a nonvolatile and irreversible manner, and is electrically writable unlike a laser fuse. Data is written into the antifuse element 202, by applying a high voltage WRITE to an insulation film in the antifuse element 202 by a level converting circuit 204, in the control of the control circuit 201.

Data in the antifuse element 202 is read out in response to activation of the load enable signal LEN, and is amplified by the sense amplifier circuit 203. Amplified data is latched by a latch circuit 205, and is output as fuse data DATA. The fuse data DATA is one bit of the address data RA1 to RAM.

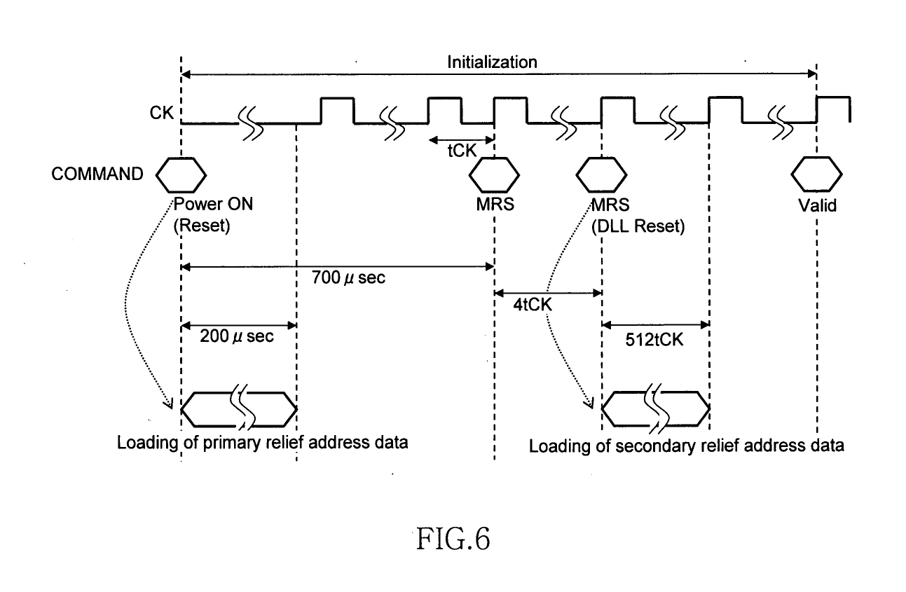

FIG. 6 is a timing chart showing a redundancy control operation of the semiconductor memory device 10 according to the present embodiment.

As shown in FIG. 6, address data used for the primary redundancy and the secondary redundancy is loaded during an initialization period of the semiconductor memory device 10.

Address data used for the primary redundancy operation is loaded during a period from immediately after power on or resetting of a power source until an input of an MRS command. A relatively long period, such as 700 microseconds, can be secured in this case. Loading of primary relief address data (the address data used for the primary redundancy operation) is completed in about 200 microseconds.

Address data used for the secondary redundancy operation is loaded during one of mode register setting periods. In the present embodiment, this address data is loaded during a DLL reset period as one of setting operations by a mode register set. The DLL reset period requires a longer period than other setting operations, because a DLL circuit needs to be locked. Specifically, while most of other setting operations are completed in 4 tCK (tCK is one clock cycle), the DLL reset period requires 512 tCK. In the present embodiment, secondary relief address data (the address data used for the primary redundancy operation) are loaded by using the DLL reset period.

Although a longer period can be secured for the DLL reset than for other setting operations, the DLL reset period is much shorter than a period from immediately after power on or resetting of a power source until an input of an MRS command, that is, a load period of the primary relief address data (the address data used for the primary redundancy operation). Further, in loading the secondary relief address data (the address data used for the secondary redundancy operation), an amplification period for the sense amplifier circuit 203 to amplify data stored by the antifuse element 202 needs to be secured. Therefore, there is no time allowance to transfer the bits of address data one by one to the secondary relief circuit (the secondary redundancy control circuit) 12 by using one transfer wiring.

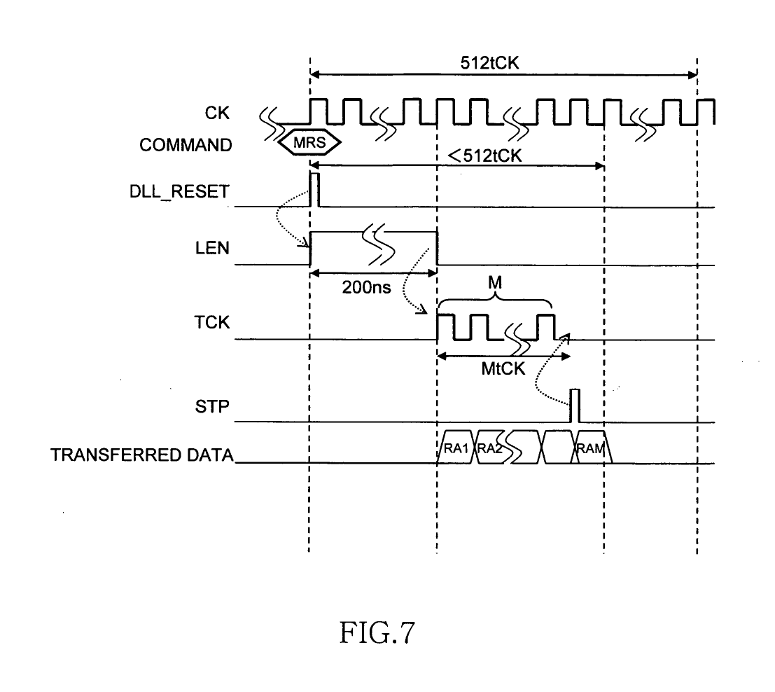

FIG. 7 is a timing chart showing a load operation of a secondary relief address data (the address data used for the secondary redundancy operation).

As shown in FIG. 7, a predetermined MRS command is issued and the control signal RST to reset the DLL circuit is activated. As a result, the control circuit 201 shown in FIG. 5 activates the load enable signal LEN during a constant period. In the example shown in FIG. 7, an activation period of the load enable signal LEN is 200 nanoseconds. This period can be regulated by a delay circuit that delays the control signal RST. Accordingly, the sense amplifier circuit 203 amplifies the data stored in the antifuse element 202, and stores the amplified data in the data latch 205. The address data RA1 to RAM are output from the antifuse element groups 110₁ to 110_{M} shown in FIG. 4 to the serial transfer circuit 120, and are loaded on N shift registers 120₁ to 120_{M} that constitute the serial transfer circuit 120.

When the load enable signal LEN is inactivated, the clock generator 170 starts outputting the transfer clock TCK synchronously with the external clock CK. Accordingly, the serial transfer circuit 120 transfers address data to the serial reception circuit 130. The address data is transferred by one defective bit by using N transfer lines 160 as described above. That is, each time when the transfer clock TCK is activated, one address data is transferred in parallel. Therefore, to complete a serial transfer of all address data, the transfer clock TCK needs to be activated at M times.

When the transfer clock TCK is activated at M times, this is detected by the set number counter 172, and the stop signal STP is output. Accordingly, supply of the transfer clock TCK to the serial transfer circuit 120 and the serial reception circuit 130 is stopped. The address data transferred to the serial reception circuit 130 is loaded on the address latch circuit 140, and the address comparison circuit 150 can detect a defective address.

As explained above, in the present embodiment, one address data including N bits is transferred in parallel by using N transfer lines 160, and this is serially transferred at M times. Therefore, the time to transfer the address data can be shortened, while reducing the number of the transfer lines 160.

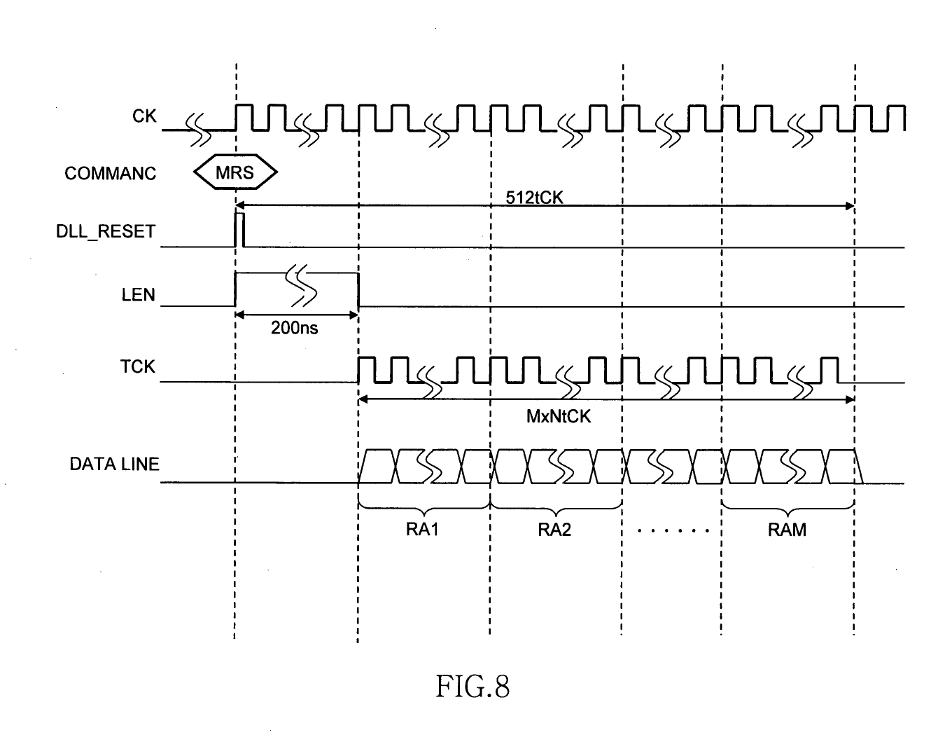

FIG. 8 is a timing chart showing an example of loading a secondary relief address data (the address data used for the secondary redundancy operation) using one transfer wiring for comparison.

As shown in FIG. 8, when each one bit of address data is transferred by using one transfer wiring, a clock number required to transfer all address data becomes N×M times, which is N times of M required in the present embodiment. Because address data includes both a row address and a column address in the secondary redundancy operation unlike in the primary redundancy operation, a bit number (=N) of address data to specify one defective bit is large. As a result, there is a risk that transfer is not completed during the DLL reset period.

On the other hand, such a problem does not occur in the present embodiment, because N transfer lines 160 are used.

It is apparent that the present invention is not limited to the above embodiments, but may be modified and changed without departing from the scope and spirit of the invention.

For example, in the above embodiment, while antifuse element groups are used for a nonvolatile address storing circuit, circuits other than antifuse circuits can be used as far as the circuit can store address data in a nonvolatile and irreversible manner.

What is claimed is:

1. A semiconductor memory device comprising:
a memory cell array that may include a plurality of first defective memory cells;
a plurality of nonvolatile address storing circuits that store respectively a plurality of first sets of defective address data, each of the first sets of defective address data indicating a corresponding one of the first defective memory cells and including a plurality of first address bits;
a serial transfer circuit that transfers in parallel the address bits of each of the first sets of defective address data and in serial the first sets of defective address data stored in each of the nonvolatile address storing circuits;
a serial reception circuit that receives in parallel the address bits of each of the first sets of defective address data and in serial the sets of defective address data from the serial transfer circuit; and
a plurality of address latch circuits that receive and store respectively the first sets of defective address data supplied from the serial reception circuit.

2. The semiconductor memory device as claimed in claim 1, wherein the nonvolatile address storing circuits supply in parallel the first sets of defective address data to the serial transfer circuit.

3. The semiconductor memory device as claimed in claim 1, wherein the serial reception circuit supplies in parallel the first sets of defective address data to the plurality of latch circuits.

4. The semiconductor memory device as claimed in claim 1, further comprising an address comparison circuit that compares each of the first sets of defective address data stored in the address latch circuits with an input address, and determines whether one of the first sets of defective address data coincides with the input address.

5. The semiconductor memory device as claimed in claim 4, further comprising:
a first redundant memory cell that replaces one of the first defective memory cells; and
a switching circuit that switches an access path to the one of the first defective memory cells to an access path to the first redundant memory cell, wherein
the comparison circuit activates a hit signal, when one of the first sets of the defective address data indicating the one of the first defective memory cells coincides with the input address, so that the switching circuit switches the access path to the one of the first defective memory cells to the access path to the first redundant memory cell.

6. The semiconductor memory device as claimed in claim 1, wherein each of the nonvolatile address storing circuits includes a plurality of antifuse elements.

7. The semiconductor memory device as claimed in claim 1, wherein the address bits of each of the first sets of the address data includes at plurality of first row address bits of the corresponding one of the first defective memory cells and a plurality of first column address bits of the corresponding one of the first defective memory cells.

8. The semiconductor memory device as claimed in claim 7, wherein the memory cell array may includes a plurality of second defective memory cells, and further comprising a plurality of additional nonvolatile address storing circuits, the additional nonvolatile address storing circuits storing respectively a plurality of second sets of defective address data, each of the second sets of defective address data including one of a plurality of second row address bits of a corresponding one of the second defective memory cells and a plurality of second column address bits of a corresponding one of the second defective memory cells.

9. The semiconductor memory device as claimed in claim 8, wherein each of the additional nonvolatile address storing circuits includes a plurality of laser fuse elements.

10. The semiconductor memory device as claimed in claim 1, further comprising a clock generator that generates a transfer clock, wherein
the serial transfer circuit transfers the first sets of defective address data in response to the transfer clock.

11. The semiconductor memory device as claimed in claim 10, further comprising a DLL circuit, and wherein the clock generator operates based on a control signal for resetting the DLL circuit.

12. The semiconductor memory device as claimed in claim 10, further comprising a set number counter that counts a clock pulse number of the transfer clock, and wherein the set number counter supplies a stopping signal to the clock generator, when a result of the count reach a predetermined value, so that the clock generator stops supplying of the transfer clock signal to the serial transfer circuit.

13. A semiconductor memory device comprising:
a memory cell array that may include a plurality of first defective memory cells;
a plurality of nonvolatile address storing circuits that store respectively a plurality of first sets of defective address data, each of the first sets of defective address data indicating a corresponding one of the first defective memory cells and including a plurality of first address bits;
a plurality of transfer lines that transfers in parallel each of the first sets of defective address data, the number of the transfer lines being equal to the number of bits of the first address bits included in each of the first defective address data; and
an address comparison circuit that compares the each of the first sets of defective address data transferred via the transfer lines with an input address, and determines whether one of the first sets of defective address data coincides with the input address.

14. The semiconductor memory device as claimed in claim 13, wherein the first address bits each of the first sets of defective address data includes a plurality of first row address bits and a plurality of first column address bits.

15. The semiconductor memory device as claimed in claim 14, wherein the memory cell array may includes a plurality of second defective memory cells, and further comprising a redundancy circuit that includes a plurality of additional nonvolatile address storing circuits, the additional nonvolatile address storing circuits storing respectively a plurality of second sets of defective address data, each of the second sets of defective address data including one of a plurality of second row address bits of a corresponding one of the second defective memory cells and a plurality of second column address bits of a corresponding one of the second defective memory cells.

16. The semiconductor memory device as claimed in claim 15, wherein each of the nonvolatile address storing circuits includes a plurality of antifuse elements and each of the additional nonvolatile address storing circuits includes a plurality of laser fuse elements.
